(19) United States
(12) Patent Application Publication
(10) Pub. No.: US 2026/0173830 A1
(43) Pub. Date: Jun. 18, 2026

(54) MANUFACTURING METHOD OF SEMICONDUCTOR DEVICE

(71) Applicant: United Semiconductor (Xiamen) Co., Ltd., Xiamen (CN)

(72) Inventors: Jian Liu, Xiamen (CN); Jinjian Ouyang, Xiamen (CN); Chin-Chun Huang, Hsinchu County (TW); Wen Yi Tan, Xiamen (CN)

(73) Assignee: United Semiconductor (Xiamen) Co., Ltd., Xiamen (CN)

(21) Appl. No.: 19/011,664

(22) Filed: Jan. 7, 2025

(30) Foreign Application Priority Data
Dec. 18, 2024 (CN) 202411874235.3

(51) Int. Cl. H01L 21/762

(52) U.S. Cl. CPC H10W 10/17; H10W 10/0143

(57) ABSTRACT

A manufacturing method of a semiconductor device includes following steps. A semiconductor substrate including a first portion located within a low voltage device region and a second portion located within a middle voltage device region is provided. A first pad oxide pattern and a second pad oxide pattern are formed above the first portion and the second portion, respectively. A first trench isolation structure and a second trench isolation structure are formed. At least a part of the first trench isolation structure is formed in the first portion and located adjacent to the first pad oxide pattern. At least a part of the second trench isolation structure is formed in the second portion and located adjacent to the second pad oxide pattern. An etching process is performed, and the second pad oxide pattern and a part of the second trench isolation structure are removed concurrently by the etching process.

### BACKGROUND OF THE INVENTION

### 1. FIELD OF THE INVENTION

The present invention relates to a manufacturing method of a semiconductor device, and more particularly, to a manufacturing method of a semiconductor device including device regions for different operation voltages.

### 2. DESCRIPTION OF THE PRIOR ART

In the integrated circuits, transistors may be different from one another in structure for different operation voltages. For example, the transistors for relatively low operation voltage may be applied in core devices, input/output (I/O) devices, and so on. The transistors capable of high voltage processing may be applied in high operation voltage environment such as CPU power supply, power management system, AC/DC converter, and high-power or power amplifier. In the embedded high voltage (eHV) process, transistor elements for different operation voltages (such as a high voltage transistor, a middle voltage transistor, and a low voltage transistor) may be disposed within one chip for the product specification, and the structures and manufacturing method of the transistors are partially different from one another. Therefore, how to improve the manufacturing process integration of the different transistor structures through structural design and/or process design so as to improve manufacturing yield and/or satisfy product specification is an ongoing research direction for people in related fields.

### SUMMARY OF THE INVENTION

A manufacturing method of a semiconductor device is provided in the present invention. An etching process is used to remove a part of a trench isolation structure and a pad oxide pattern adjacent to the trench isolation structure for process simplification and/or manufacturing cost reduction.

According to an embodiment of the present invention, a manufacturing method of a semiconductor device is provided. The manufacturing method includes the following steps. A semiconductor substrate is provided, and the semiconductor substrate includes a first portion located within a low voltage device region and a second portion located within a middle voltage device region. A first pad oxide pattern and a second pad oxide pattern are formed above the first portion and the second portion, respectively. A first trench isolation structure and a second trench isolation structure are formed. At least a part of the first trench isolation structure is formed in the first portion and located adjacent to the first pad oxide pattern, and at least a part of the second trench isolation structure is formed in the second portion and located adjacent to the second pad oxide pattern. An etching process is performed. The second pad oxide pattern and a part of the second trench isolation structure are removed concurrently by the etching process.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1-15 are schematic drawings illustrating a manufacturing method of a semiconductor device according to an embodiment of the present invention, wherein FIG. 2 is a schematic drawing in a step subsequent to FIG. 1, FIG. 3 is a schematic drawing in a step subsequent to FIG. 2, FIG. 4 is a schematic drawing in a step subsequent to FIG. 3, FIG. 5 is a schematic drawing in a step subsequent to FIG. 4, FIG. 6 is a schematic drawing in a step subsequent to FIG. 5, FIG. 7 is a schematic drawing in a step subsequent to FIG. 6, FIG. 8 is a schematic drawing in a step subsequent to FIG. 7, FIG. 9 is a schematic drawing in a step subsequent to FIG. 8, FIG. 10 is a schematic drawing in a step subsequent to FIG. 9, FIG. 11 is a schematic drawing in a step subsequent to FIG. 10, FIG. 12 is a schematic drawing in a step subsequent to FIG. 11, FIG. 13 is a schematic drawing in a step subsequent to FIG. 12, FIG. 14 is a schematic drawing in a step subsequent to FIG. 13, and FIG. 15 is a schematic drawing in a step subsequent to FIG. 14.

### DETAILED DESCRIPTION

The present invention has been particularly shown and described with respect to certain embodiments and specific features thereof. The embodiments set forth herein below are to be taken as illustrative rather than limiting. It should be readily apparent to those of ordinary skill in the art that various changes and modifications in form and detail may be made without departing from the spirit and scope of the present invention.

Before the further description of the preferred embodiment, the specific terms used throughout the text will be described below.

The terms “on,” “above,” and “over” used herein should be interpreted in the broadest manner such that “on” not only means “directly on” something but also includes the meaning of “on” something with an intermediate feature or a layer therebetween, and that “above” or “over” not only means the meaning of “above” or “over” something but can also include the meaning it is “above” or “over” something with no intermediate feature or layer therebetween (i.e., directly on something).

The ordinal numbers, such as “first”, “second”, etc., used in the description and the claims are used to modify the elements in the claims and do not themselves imply and represent that the claim has any previous ordinal number, do not represent the sequence of some claimed element and another claimed element, and do not represent the sequence of the manufacturing methods, unless an addition description is accompanied. The use of these ordinal numbers is only used to make a claimed element with a certain name clear from another claimed element with the same name.

The term “etch” is used herein to describe the process of patterning a material layer so that at least a portion of the material layer after etching is retained. When “etching” a material layer, at least a portion of the material layer is retained after the end of the treatment. In contrast, when the material layer is “removed”, substantially all the material layer is removed in the process. However, in some embodiments, “removal” is considered to be a broad term and may include etching.

The term “forming” or the term “disposing” are used hereinafter to describe the behavior of applying a layer of material to the substrate. Such terms are intended to describe any possible layer forming techniques including, but not limited to, thermal growth, sputtering, evaporation, chemical vapor deposition, epitaxial growth, electroplating, and the like.

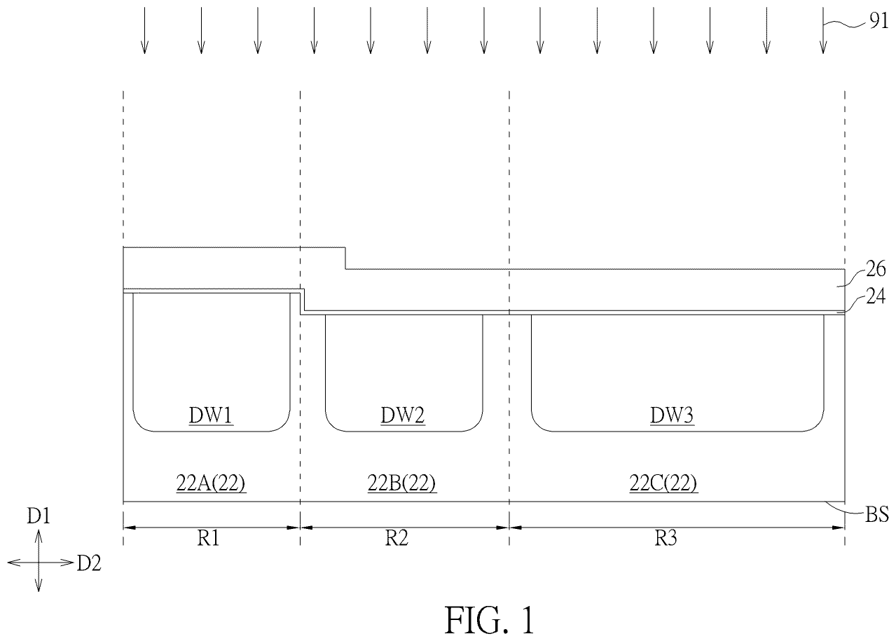

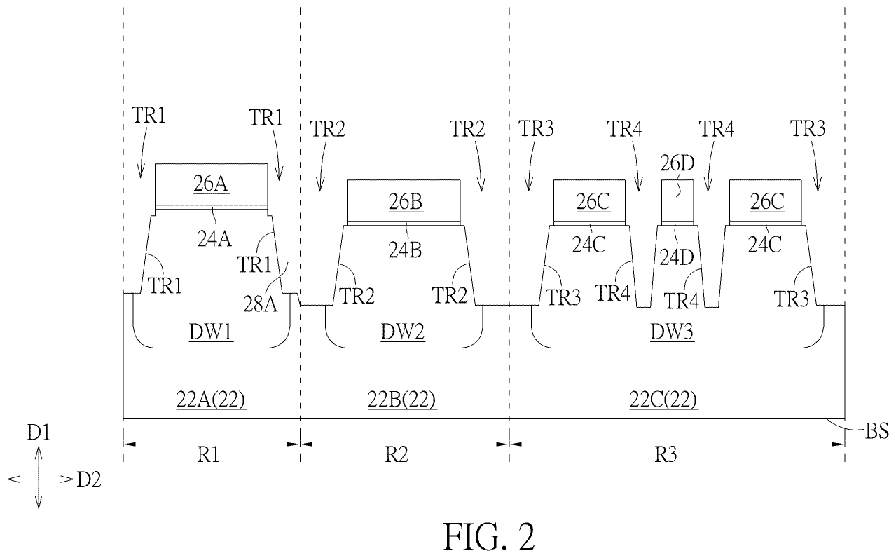

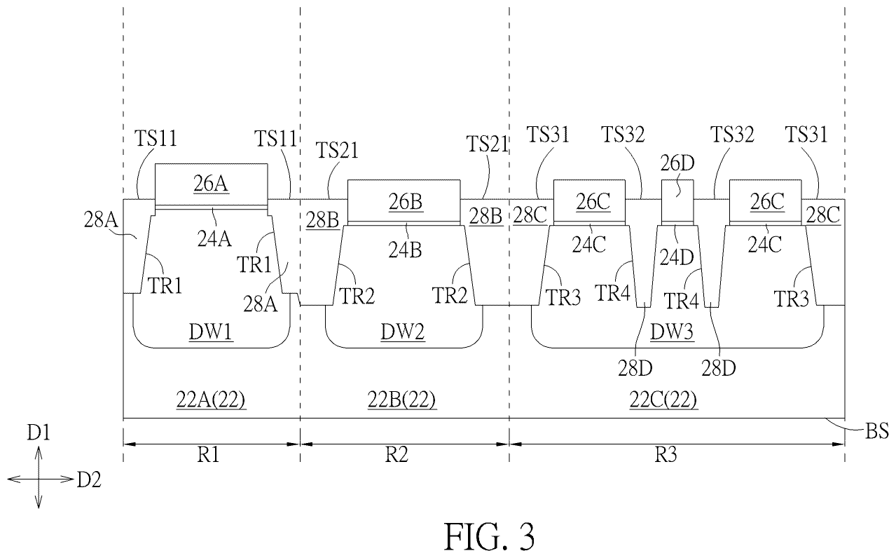

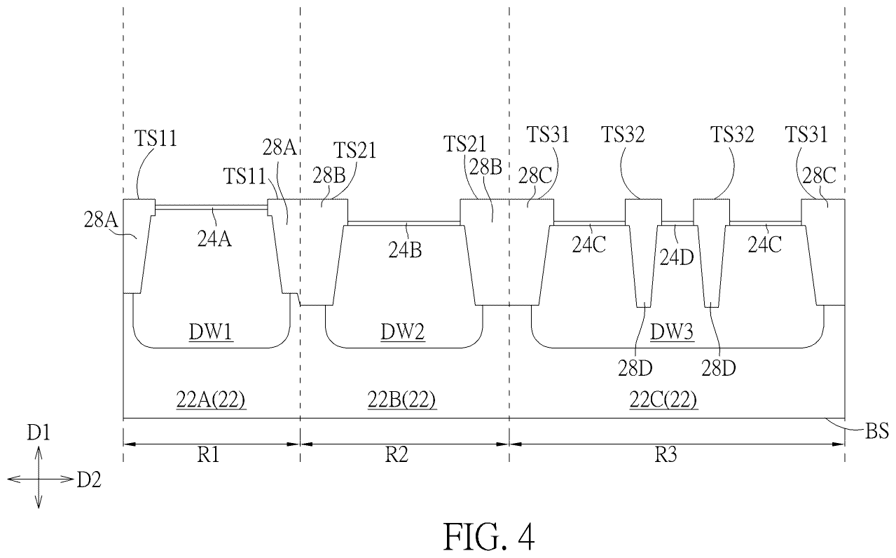

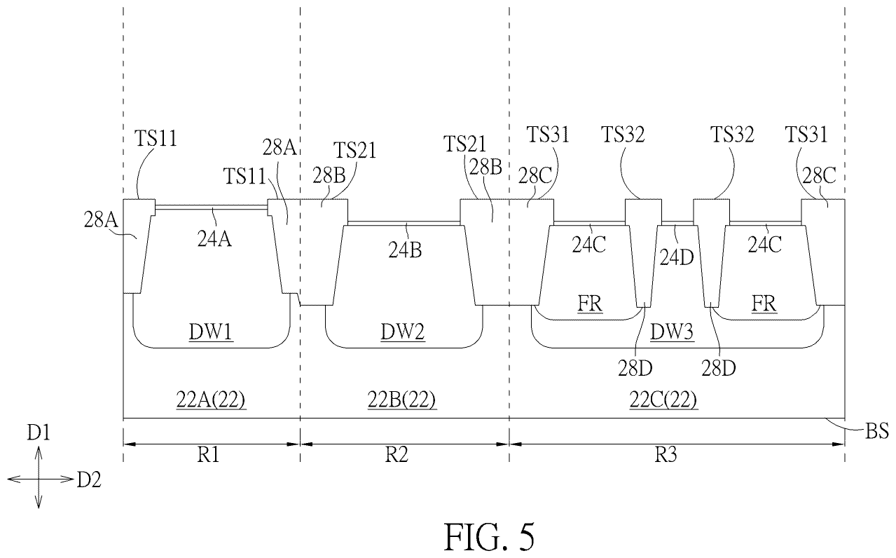

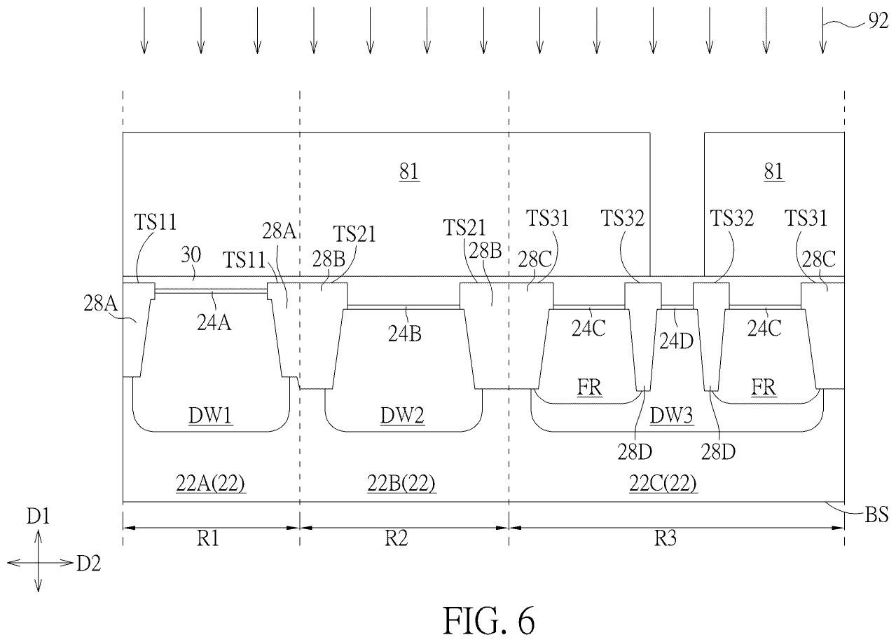

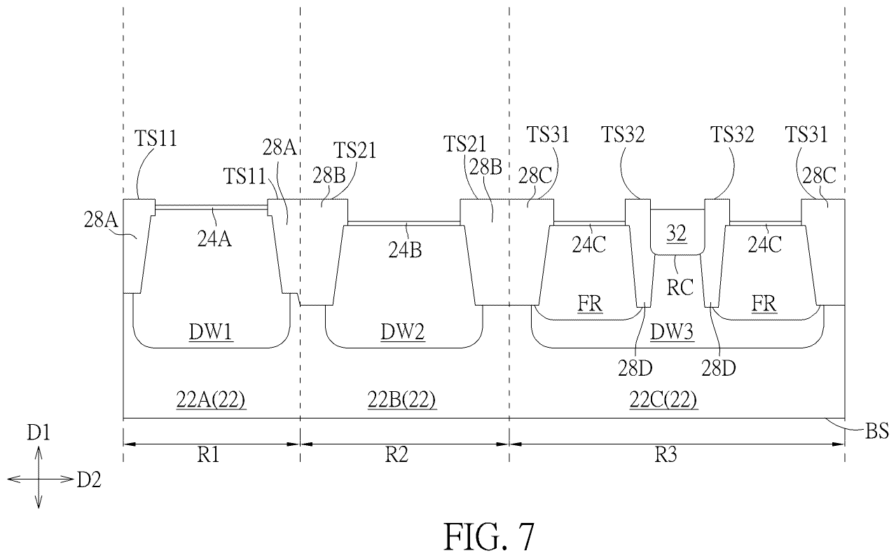

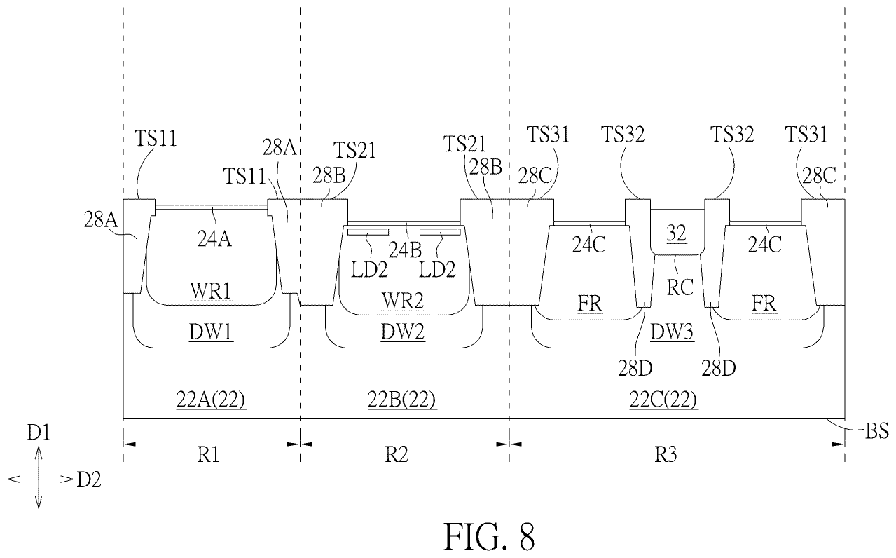

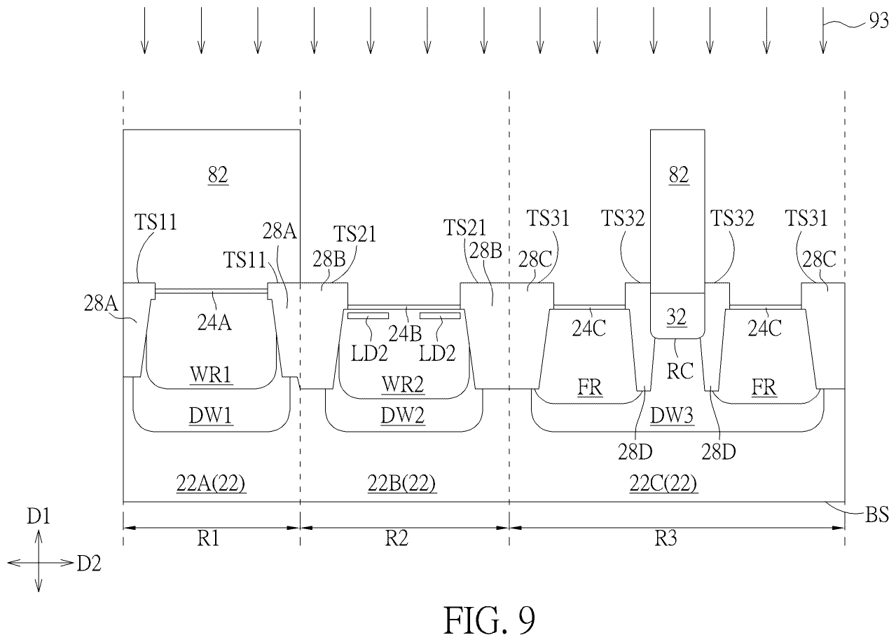

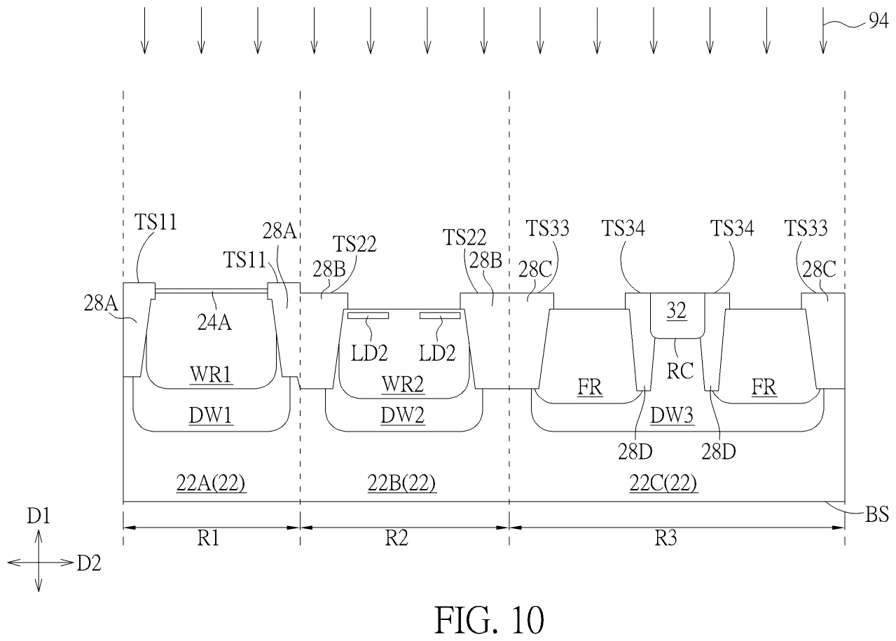

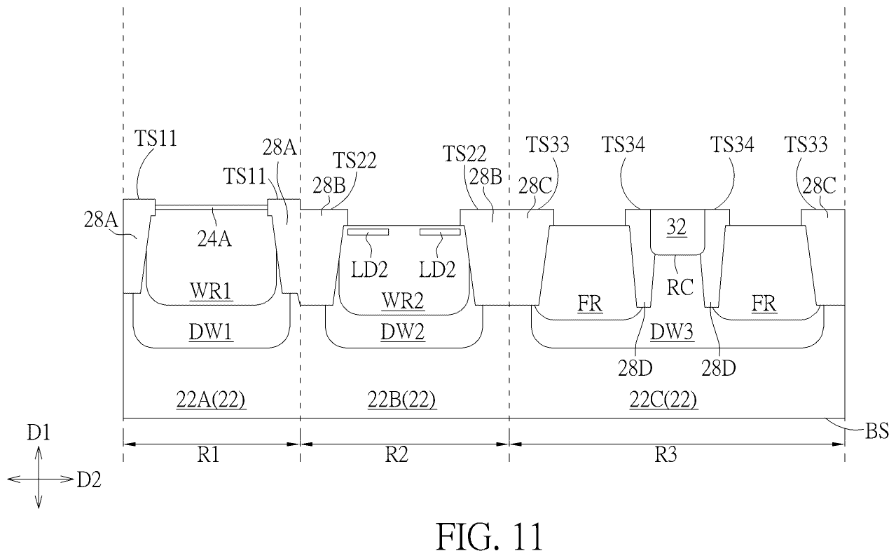

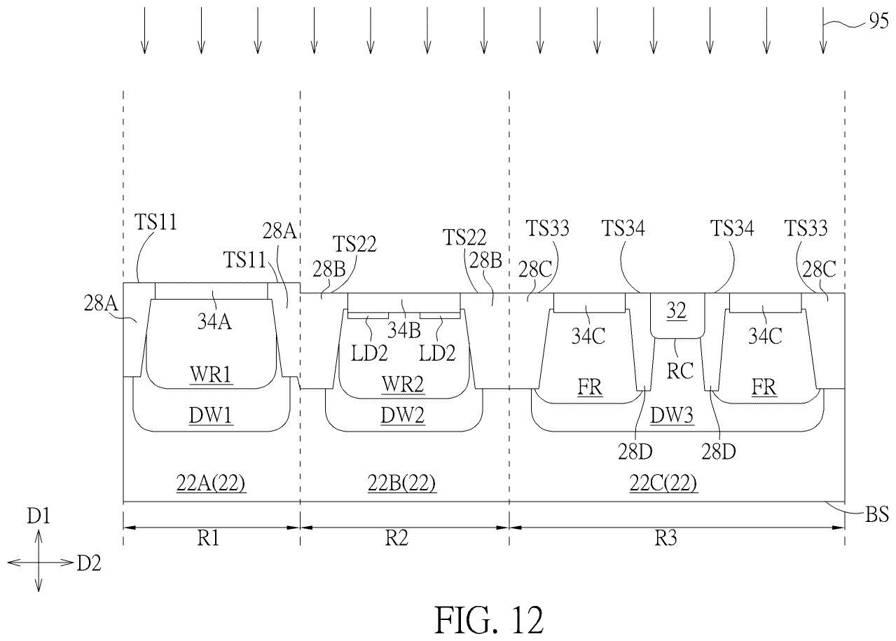

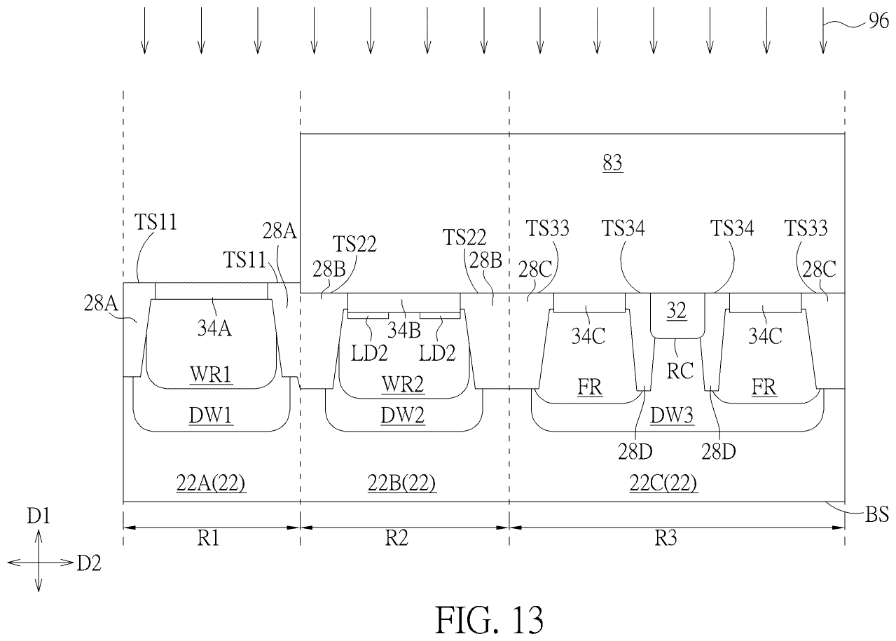

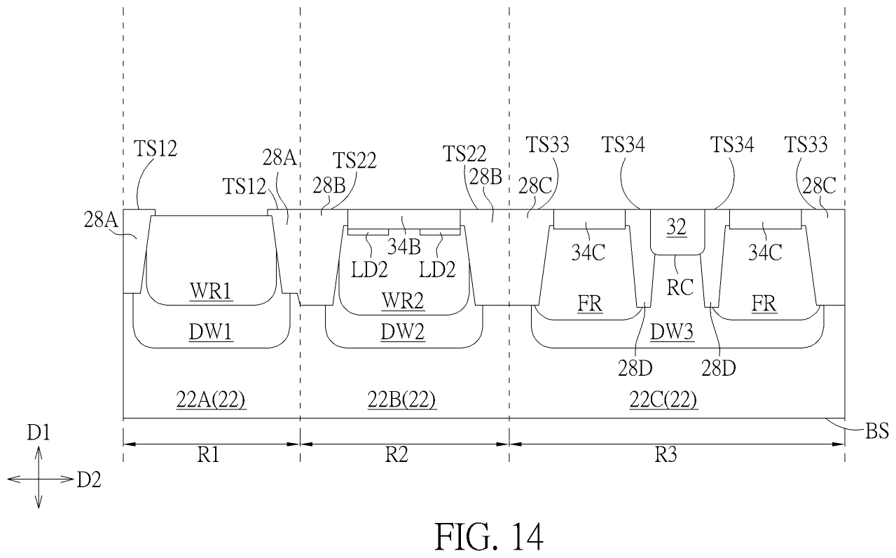

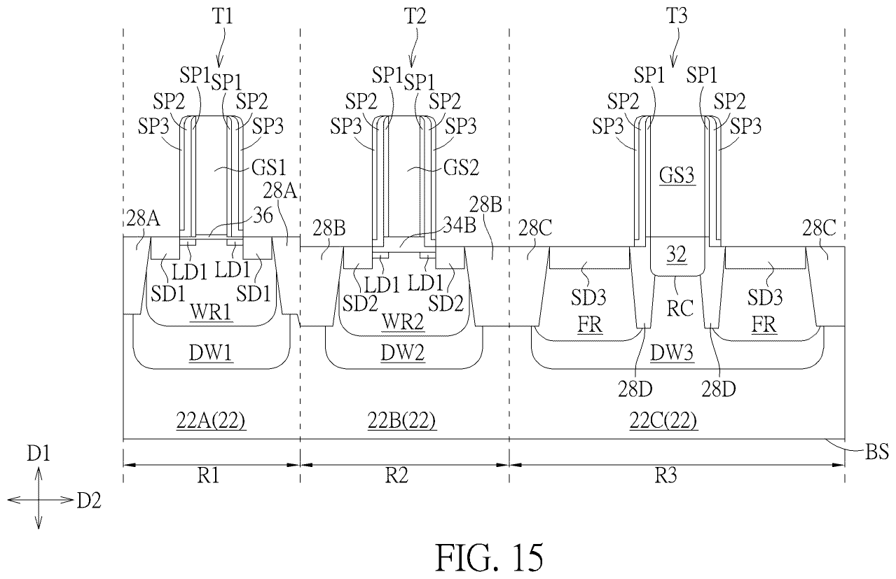

Please refer to FIGS. 1-15. FIGS. 1-15 are schematic drawings illustrating a manufacturing method of a semiconductor device according to an embodiment of the present invention, wherein FIG. 2 is a schematic drawing in a step subsequent to FIG. 1, FIG. 3 is a schematic drawing in a step subsequent to FIG. 2, FIG. 4 is a schematic drawing in a step subsequent to FIG. 3, FIG. 5 is a schematic drawing in a step subsequent to FIG. 4, FIG. 6 is a schematic drawing in a step subsequent to FIG. 5, FIG. 7 is a schematic drawing in a step subsequent to FIG. 6, FIG. 8 is a schematic drawing in a step subsequent to FIG. 7, FIG. 9 is a schematic drawing in a step subsequent to FIG. 8, FIG. 10 is a schematic drawing in a step subsequent to FIG. 9, FIG. 11 is a schematic drawing in a step subsequent to FIG. 10, FIG. 12 is a schematic drawing in a step subsequent to FIG. 11, FIG. 13 is a schematic drawing in a step subsequent to FIG. 12, FIG. 14 is a schematic drawing in a step subsequent to FIG. 13, and FIG. 15 is a schematic drawing in a step subsequent to FIG. 14. A manufacturing method of a semiconductor device is provided in this embodiment, and the manufacturing method includes the following steps. Firstly, as shown in FIG. 1, a semiconductor substrate 22 is provided, and the semiconductor substrate 22 includes a first portion 22A located within a low voltage device region R1 and a second portion 22B located within a middle voltage device region R2. As shown in FIG. 2, a first pad oxide pattern (such as a pad oxide pattern 24A) and a second pad oxide pattern (such as a pad oxide pattern 24B) are formed above the first portion 22A and the second portion 22B, respectively. As shown in FIG. 2 and FIG. 3, a first trench isolation structure (such as a trench isolation structure 28A) and a second trench isolation structure (such as a trench isolation structure 28B) are formed. At least a part of the trench isolation structure 28A is formed in the first portion 22A and located adjacent to the pad oxide pattern 24A, and at least a part of the trench isolation structure 28B is formed in the second portion 22B and located adjacent to the pad oxide pattern 24B. As shown in FIG. 9 and FIG. 10, an etching process 93 is performed. The pad oxide pattern 24B and a part of the trench isolation structure 28B are removed concurrently by the etching process 93. The etching process 93 may include a buffer oxide etching (BOE) process or other suitable etching approaches. The pad oxide pattern 24B may be removed concurrently by the same etching process configured to partially etch the trench isolation structure 28B and modify the height of the trench isolation structure 28B, and the purposes of process simplification and/or manufacturing cost reduction may be achieved accordingly.

As shown in FIG. 1, a vertical direction D1 may be regarded as a thickness direction of the semiconductor substrate 22. The semiconductor substrate 22 may have a top surface and a bottom surface BS opposite to the top surface in the vertical direction D1, and the pad oxide pattern 24A and the pad oxide pattern 24B described above may be formed at the side of the top surface of the semiconductor substrate 22. The trench isolation structure 28A and the trench isolation structure 28B may respectively extend from the top surface of the semiconductor substrate 22 towards the bottom surface BS in the vertical direction D1 without penetrating through the semiconductor substrate 22. A horizontal direction substantially orthogonal to the vertical direction D1 (such as a horizontal direction D2, but not limited thereto) may be parallel with the bottom surface BS, but not limited thereto. In this description, a distance between the bottom surface BS of the semiconductor substrate 22 and a relatively higher location and/or a relatively higher part in the vertical direction D1 may be greater than a distance between the bottom surface BS of the semiconductor substrate 22 and a relatively lower location and/or a relatively lower part in the vertical direction D1. The bottom or a lower portion of each component may be closer to the bottom surface BS of the semiconductor substrate 22 in the vertical direction D1 than the top or upper portion of this component. Another component disposed above a specific component may be regarded as being relatively far from the bottom surface BS of the semiconductor substrate 22 in the vertical direction D1, and another component disposed under a specific component may be regarded as being relatively close to the bottom surface BS of the semiconductor substrate 22 in the vertical direction D1. Additionally, in this description, a top surface and a top portion of a specific component may include the topmost surface and the topmost portion of this component in the vertical direction D1, and a bottom surface and a bottom portion of a specific component may include the bottommost surface and the bottommost portion of this component in the vertical direction D1, but not limited thereto. In this description, the condition that a certain component is disposed between two other components in a specific direction may include but is not limited to a condition that the certain component is sandwiched between the two other components in the specific direction.

Specifically, the manufacturing method in this embodiment may include but is not limited to the following steps and/or the following features. As shown in FIG. 1, the semiconductor substrate 22 may further include a third portion 22C located within a high voltage device region R3, and the semiconductor substrate 22 may include a silicon base substrate, a silicon germanium semiconductor substrate, a silicon-on-insulator (SOI) substrate, or a semiconductor substrate made of other suitable materials. In addition, a pad oxide layer 24 may be formed on the semiconductor substrate 22 and located above the first portion 22A, the second portion 22B, and the third portion 22C in the vertical direction D1, and a mask layer 26 may be formed one the pad oxide layer 24 and located above the first portion 22A, the second portion 22B, and the third portion 22C in the vertical direction D1. In some embodiments, before the steps of forming the pad oxide layer 24 and the mask layer 26, the top surfaces of the second portion 22B and the third portion 22C may be lower than the top surface of the first portion 22A by a suitable method (such as but not limited to a method of partially oxidizing the semiconductor substrate 22 and removing the oxide), and the top surfaces of the pad oxide layer 24 and the mask layer 26 located above the second portion 22B and the third portion 22C may be therefore lower than the top surfaces of the pad oxide layer 24 and the mask layer 26 located above the first portion 22A, respectively. The pad oxide layer 24 may include silicon oxide or other suitable oxide materials, and the mask layer 26 may include silicon nitride or other suitable mask materials.

In some embodiments, a first deep well region (such as a deep well region DW1), a second deep well region (such as a deep well region DW2), and a third deep well region (such as a deep well region DW3) may be formed in the first portion 2A, the second portion 22B, and the third portion 22C, respectively, by an implantation process before the pad oxide layer 24 is formed according to some design considerations, but not limited thereto. The conductivity type of the deep well region DW1, the deep well region DW2, and the deep well region DW3 may be complementary to the conductivity type of the semiconductor substrate 22. For example, when the semiconductor substrate 22 is a p-type semiconductor substrate (such as a p-type silicon semiconductor substrate), the deep well region DW1, the deep well region DW2, and the deep well region DW3 may be n-type deep well regions, but not limited thereto. Subsequently, as shown in FIG. 1 and FIG. 2, a patterning process 91 may be performed. The first portion 22A and the deep well region DW1 may be partially removed by the patterning process 91 so as to form a first trench (such as a trench TR1) in the first portion 22A, the second portion 22B and the deep well region DW2 may be partially removed by the patterning process 91 so as to form a second trench (such as a trench TR2) in the second portion 22B, and the third portion 22C and the deep well region DW3 may be partially removed by the patterning process 91 so as to form a third trench (such as a trench TR3) and a fourth trench (such as a trench TR4) in the third portion 22C.

In addition, the pad oxide layer 24 may be patterned to be the pad oxide pattern 24A, the pad oxide pattern 24B, a third pad oxide pattern (such as a pad oxide pattern 24C), and a fourth pad oxide pattern (such as a pad oxide pattern 24D) by the patterning process 91. The pad oxide pattern 24A is formed above the first portion 22A, the pad oxide pattern 24B is formed above the second portion 22B, and the pad oxide pattern 24C and the pad oxide pattern 24D are formed above the third portion 22C. The mask layer 26 may be patterned to be a first mask pattern (such as a mask pattern 26A), a second mask pattern (such as a mask pattern 26B), a third mask pattern (such as a mask pattern 26C), and a fourth mask pattern (such as a mask pattern 26D) by the patterning process 91. The mask pattern 26A is formed above the first portion 22A, the mask pattern 26B is formed above the second portion 22B, and the mask pattern 26C and the mask pattern 26D are formed above the third portion 22C. The pad oxide pattern 24A is sandwiched between the mask pattern 26A and the first portion 22A in the vertical direction D1, the pad oxide pattern 24B is sandwiched between the mask pattern 26B and the second portion 22B in the vertical direction D1, the pad oxide pattern 24C is sandwiched between the mask pattern 26C and the third portion 22C in the vertical direction D1, and the pad oxide pattern 24D is sandwiched between the mask pattern 26D and the third portion 22C in the vertical direction D1. The pad oxide pattern 24A, the pad oxide pattern 24B, the pad oxide pattern 24C, and the pad oxide pattern 24D may be regarded as being formed concurrently by the same process. The mask pattern 26A, the mask pattern 26B, the mask pattern 26C, and the mask pattern 26D may be regarded as being formed concurrently by the same process. The trench TR1, the trench TR2, the trench TR3, and the trench TR4 may be regarded as being formed concurrently by the same process.

In some embodiments, the patterning process 91 may include a photolithographic process and a corresponding etching process, a patterned photoresist formed in the photolithographic process may be used as an etching mask in the step of etching the mask layer 26, and the patterned photoresist and/or the mask patterns formed by etching the mask layer 26 may be used as an etching mask in the step of etching the pad oxide layer 24 and/or the step of etching the semiconductor substrate 22. The patterned photoresist may be removed after the trenches described above are formed. Therefore, the mask pattern 26A, the mask pattern 26B, the mask pattern 26C, the mask pattern 26D, the pad oxide pattern 24A, the pad oxide pattern 24B, the pad oxide pattern 24C, the pad oxide pattern 24D, the trench TR1, the trench TR2, the trench TR3, and the trench TR4 may be formed by the same patterning process 91, but not limited thereto. In some embodiments, the trenches, the pad oxide patterns, and the mask patterns illustrated in FIG. 2 may also be formed respectively by other suitable approaches or formed concurrently by other suitable approaches according to some design considerations. In addition, because the top surface of the first portion 22A is higher than the top surface of the second portion 22B and the top surface of the third portion 22C, the top surface of the pad oxide pattern 24A may be higher than the top surfaces of the pad oxide pattern 24B, the pad oxide pattern 24C, and the pad oxide pattern 24D in the vertical direction D1, the top surface of the mask pattern 26A may be higher than the top surfaces of the mask pattern 26B, the mask pattern 26C, and the mask pattern 26D in the vertical direction D1, and the bottom of the trench TR1 may be higher than the bottoms of the trench TR2, the trench TR3, and the trench TR4 in the vertical direction D1, but not limited thereto.

As shown in FIG. 2 and FIG. 3, after the patterning process described above, the trench isolation structure 28A, the trench isolation structure 28B, a third trench isolation structure (such as a trench isolation structure 28C), and a fourth trench isolation structure (such as a trench isolation structure 28D) may be formed. Therefore, the mask patterns (such as the mask pattern 26A, the mask pattern 26B, the mask pattern 26C, and the mask pattern 26D) and the pad oxide patterns (such as the pad oxide pattern 24A, the pad oxide pattern 24B, the pad oxide pattern 24C, and the pad oxide pattern 24D) may be formed before the trench isolation structures (such as the trench isolation structure 28A, the trench isolation structure 28B, the trench isolation structure 28C, and the trench isolation structure 28D) are formed. The trench isolation structure 28A, the trench isolation structure 28B, the trench isolation structure 28C, and the trench isolation structure 28D may be formed in the trench TR1, the trench TR2, the trench TR3, and the trench TR4, respectively. At least a part of the trench isolation structure 28C is formed in the third portion 22C and located adjacent to the pad oxide pattern 24C, and at least a part of the trench isolation structure 28D is formed in the third portion 22C and located adjacent to the pad oxide pattern 24C and the pad oxide pattern 24D. In some embodiments, a single layer or multiple layers of insulation materials (such as an oxide insulation material or other suitable insulation materials) may be formed and the trenches (such as the trench TR1, the trench TR2, the trench TR3, and the trench TR4) may be filled with the insulation material, and a planarization process and an etching back process may be performed to the insulation material for forming the trench isolation structures. Therefore, the trench isolation structure 28A, the trench isolation structure 28B, the trench isolation structure 28C, and the trench isolation structure 28D may be regarded as being formed concurrently by the same process. In addition, a top surface TS11 of the trench isolation structure 28A may be lower than a top surface of the mask pattern 26A, a top surface TS21 of the trench isolation structure 28B may be lower than a top surface of the mask pattern 26B, a top surface TS31 of the trench isolation structure 28C may be lower than a top surface of the mask pattern 26C, a top surface TS32 of the trench isolation structure 28D may be lower than a top surface of the mask pattern 26C and a top surface of the mask pattern 26D, and the top surface TS11, the top surface TS21, the top surface TS31, and the top surface TS32 may be substantially coplanar, but not limited thereto.

As shown in FIG. 3 and FIG. 4, after the trench isolation structures are formed, the mask patterns may be removed for exposing each of the pad oxide patterns. Subsequently, as shown in FIG. 5, a drift region FR may be formed in the third portion 22C. In some embodiments, the deep well region DW3 may be formed in the third portion 22C before the trench isolation structure 28C and the trench isolation structure 28D are formed, the drift region FR may be formed in the deep well region DW3, and a conductivity type of the drift region FR may be complementary to the conductivity type of the deep well region DW3, but not limited thereto. In some embodiments, the drift region FR may be formed directly in the third portion 22C without forming the deep well region DW3, and the conductivity type of the drift region FR may be complementary to the conductivity type of the semiconductor substrate 22. In some embodiments, two trench isolation structures 28D, two drift regions FR, and two pad oxide patterns 24C may be formed. The trench isolation structure 28C may surround the two trench isolation structures 28D, the two drift regions FR, the two pad oxide patterns 24C and the pad oxide pattern 24D in the horizontal direction D2. The pad oxide pattern 24D may be located between the two trench isolation structures 28D in the horizontal direction D2. Each of the pad oxide patterns 24C and each of the drift regions FR may be located between the trench isolation structure 28C and the trench isolation structure 28D in the horizontal direction D2.

As shown in FIG. 6 and FIG. 7, after the drift region FR is formed, a second gate oxide layer (such as a gate oxide layer 32) may be formed. At least a part of the gate oxide layer 32 is formed in the third portion 22C, and a thickness of the gate oxide layer 32 is greater than a thickness of the pad oxide pattern 24C. In some embodiments, a method of forming the gate oxide layer 32 may include but is not limited to the following steps. As shown in FIG. 6, a mask layer 30 may be formed covering the trench isolation structures and the pad oxide patterns, a patterned mask layer 81 may be formed on the mask layer, and an etching process 92 using the patterned mask layer 81 as an etching mask may be performed. The mask layer 30 may include silicon nitride or other suitable mask materials, and the patterned mask layer 81 may include patterned photoresist or other suitable materials. As shown in FIG. 6 and FIG. 7, a part of the semiconductor substrate 22 (such as a part of the third portion 22C), a part of the trench isolation structure 28D, and at least a part of the pad oxide pattern 24D may be removed by the etching process 92 for forming a recess RC, the gate oxide layer 32 may be formed in the recess RC subsequently, and the mask layer 30 may be removed. In some embodiments, the gate oxide layer 32 may be formed by performing an oxidation process to the semiconductor substrate 22 exposed by the recess RC, and the oxidation process may include a thermal oxidation process (such as a RTO process) or other suitable oxidation approaches.

As shown in FIG. 8, after the trench isolation structures and the gate oxide layer 32 are formed, a first well region (such as a well region WR1) and a second well region (such as a well region WR2) may be formed in the first portion 22A and the second portion 22B, respectively, and two lightly doped regions LD2 may be formed in the well region WR2. The well region WR1 and the well region WR2 may be formed in the deep well region DW1 and the deep well region DW2, respectively. A conductivity type of the well region WR1 and a conductivity type of the well regionWR2 may be identical to or different from the conductivity type of the deep well region DW1 and the conductivity type of the deep well regionDW2, respectively, according to some design considerations, and a conductivity type of the lightly doped region LD2 may be complementary to the conductivity type of the well region WR2. In some embodiments, each of the deep well regions, each of the well regions, each of the lightly doped regions, and the drift region FR may respectively include a doped region formed in the semiconductor substrate 22 by a suitable doping process (such as an ion implantation process, but not limited thereto).

As shown in FIG. 9 and FIG. 10, the etching process 93 described above may be performed after the well region WR1, the well region WR2, and the lightly doped regions LD2 are formed. In some embodiments, a patterned mask layer 82 may be formed covering the gate oxide layer 32, the pad oxide pattern 24A, and the trench isolation structure 28A. The gate oxide layer 32, the pad oxide pattern 24A, and the trench isolation structure 28A may be covered by the patterned mask layer 82 during the etching process 93 and are not etched by the etching process 93, and the patterned mask layer 82 may be removed after the etching process 93. The etching process 93 may be used to reduce the height of the trench isolation structure without being covered by the patterned mask layer 82, and the pad oxide patterns without being covered by the patterned mask layer 82 may be removed by the etching process 93 also, so as to expose a part of the semiconductor substrate 22 (such as a part of the well region WR2 and a part of the drift region FR). Therefore, the pad oxide pattern 24B and a part of the trench isolation structure 28B may be removed concurrently by the etching process 93, and the pad oxide pattern 24C, a part of the trench isolation structure 28C, and a part of the trench isolation structure 28D may be removed concurrently by the etching process 93 also. Before the etching process 93, the top surface TS11 of the trench isolation structure 28A, the top surface TS21 of the trench isolation structure 28B, the top surface TS31 of the trench isolation structure 28C, and the top surface TS32 of the trench isolation structure 28D may be substantially coplanar. A top surface of the trench isolation structure 28B after the etching process 93 (such as a top surface TS22) may be lower than the top surface TS21 of the trench isolation structure 28B before the etching process 93 and a top surface of the trench isolation structure 28A after the etching process 93 (such as the top surface TS11) in the vertical direction D1. A top surface of the trench isolation structure 28C after the etching process 93 (such as a top surface TS33) may be lower than the top surface TS31 of the trench isolation structure 28C before the etching process 93 and the top surface TS11 of the trench isolation structure 28A after the etching process 93 in the vertical direction D1. A top surface of the trench isolation structure 28D after the etching process 93 (such as a top surface TS34) may be lower than the top surface TS32 of the trench isolation structure 28D before the etching process 93 and the top surface TS11 of the trench isolation structure 28A after the etching process 93 in the vertical direction D1.

As shown in FIGS. 9-12, after the etching process 93, a first gate oxide layer (such as a gate oxide layer 34B) may be formed on the second portion 22B, an oxide layer 34A may be formed on the first portion 22A, and an oxide layer 34C may be formed on the third portion 22C. A thickness of the gate oxide layer 34B may be greater than a thickness of the pad oxide pattern 24B and less than the thickness of the gate oxide layer 32, but not limited thereto. In some embodiments, the oxide layer 34A, the gate oxide layer 34B, and the oxide layer 34C may be formed concurrently by a formation process 95, and the formation process 95 may include an oxidation process or other suitable manufacturing method. In some embodiments, the pad oxide pattern 24A may remain on the first portion 22A after the etching process 93, and the pad oxide pattern 24A may become at least a part of the oxide layer 34A by the formation process 95. For example, the semiconductor substrate 22 (or the well region WR1) located under the pad oxide pattern 24A may be partially oxidized by the formation process 95 and become the oxide layer 34A including the pad oxide pattern 24A, but not limited thereto. Additionally, in some embodiments, a cleaning process 94 may be performed to the semiconductor substrate 22 after the etching process 93 and before the formation process 95, and the pad oxide pattern 24A may remain on the first portion 22A after the cleaning process 94. The cleaning process 94 may be regarded as a pre-clean step performed before the formation process 95, and the cleaning process 94 may include standard clean 1 (SC-1 ), standard clean 2 (SC-2), or other suitable cleaning approaches. A cleaning solution mixed with ammonia hydroxide, hydrogen peroxide, and deionized water in a specific ratio may be used in the standard clean 1, and a cleaning solution mixed with hydrogen chloride, hydrogen peroxide, and deionized water in a specific ratio may be used in the standard clean 2. It is worth noting that, because the pad oxide pattern 24B and the pad oxide pattern 24C are removed by the etching process 93, the cleaning process 94 performed before the formation process 95 does not need to include a cleaning step for removing oxide (such as a DHF cleaning step), and related negative influence (such as damage to the trench isolation structures) may be avoided accordingly, but not limited thereto.

In the manufacturing method of the present invention, the etching process 93 may be performed after the step of forming the gate oxide layer 32 and before the step of forming the gate oxide layer 34B for removing the pad oxide pattern 24B and a part of the trench isolation structure 28B located within the middle voltage device region R2 and a part of the trench isolation structure 28C, a part of the trench isolation structure 28D, and the pad oxide pattern 24C located within the high voltage device region R3 concurrently. The purposes of process simplification and/or manufacturing cost reduction may be achieved accordingly.

As shown in FIG. 13 and FIG. 14, a patterned mask layer 83 may be formed covering the trench isolation structure 28B, the gate oxide layer 34B, the trench isolation structure 28C, the trench isolation structure 28D, the oxide layer 34C, and the gate oxide layer 32, and an etching process 96 suing the patterned mask layer 83 as an etching mask may be performed for removing the oxide layer 34A and a part of the trench isolation structure 28 concurrently. The etching process 96 may include a BOE process or other suitable etching approaches. A top surface of the trench isolation structure 28A after the etching process 96 (such as a top surface TS12) may be lower than the top surface TS11 of the trench isolation structure 28A before the etching process 96 in the vertical direction D1. As shown in FIG. 14 and FIG. 15, in some embodiments, the oxide layer 34C may be removed and the top surfaces of the trench isolation structure 28B, the trench isolation structure 28C, and the trench isolation structure 28D may be further lowered. A gate oxide layer 36, two lightly doped regions LD1, two source/drain regions SD1, two source/drain regions SD2, two source/drain regions SD3, a gate structure GS1, a gate structure GS2, a gate structure GS3, a spacer SP1, a spacer SP2, and a spacer SP3 may be formed. The gate oxide layer 36 is formed on the first portion 22A, and the gate structure GS1 is formed on the gate oxide layer 36. The two source/drain region SD1 may be at least partly formed in the well region WR1 and located at two opposite sides of the gate structure GS1 in the horizontal direction D2. The lightly doped region LD1 is formed in the well region WR1 and located between the gate structure GS1 and the source/drain region SD1. The gate structure GS2 is formed on the gate oxide layer 34B, the two source/drain regions SD2 may be at least partly formed in the well region WR2 and located at two opposite sides of the gate structure GS2 in the horizontal direction D2, and the lightly doped region LD2 is located between the gate structure GS2 and the source/drain region SD2. The gate structure GS3 is formed on the gate oxide layer 32. The two source/drain regions SD3 may be formed in the two drift regions FR, respectively, and located at two opposite sides of the gate structure GS3 in the horizontal direction D2.

Each of the source/drain regions may include a doped region, an epitaxial structure, or other suitable materials and/or structures. Each of the gate structures may include a gate dielectric layer and a gate electrode, the gate dielectric layer may include a high dielectric constant (high-k) dielectric material or other suitable dielectric materials, and the gate electrode may include a non-metallic electrically conductive material (such as doped polysilicon) or a metallic electrically conductive material, such as a metal gate structure composed of a work function layer and a low electrical resistivity layer stacked with one another, but not limited thereto. In some embodiments, the gate structure described above may be replaced with a metal gate and a gate dielectric layer in subsequent processes (such as a replacement metal gate process), and the gate structure GS1, the gate structure GS2, and the gate structure GS3 may also be regarded as dummy gate structures including a dummy gate material, such as polysilicon, but not limited thereto. The spacer SP1, the spacer SP2, and the spacer SP3 may be stacked and disposed on the sidewalls of the gate structure GS1, the gate structure GS2, and the gate structure GS3. The spacer SP1, the spacer SP2, and the spacer SP3 may include a nitride insulation material, an oxide insulation material, or other suitable insulation materials.

In some embodiments, a transistor structure T1 located within the low voltage device region R1 may include the gate structure GS1, the gate oxide layer 36, the lightly dope regions LD1, the source/drain regions SD1, the well region WR1, and the deep well region DW1. A transistor structure T2 located within the middle voltage device region R2 may include the gate structure GS2, the gate oxide layer 34B, the lightly dope regions LD2, the source/drain regions SD2, the well region WR2, and the deep well region DW2. A transistor structure T3 located within the high voltage device region R3 may include the gate structure GS3, the gate oxide layer 32, the drift regions FR, the trench isolation structure 28D, and the deep well region DW3. The thickness of the gate oxide layer 32 is greater than the thickness of the gate oxide layer 34B, and the thickness of the gate oxide layer 34B is greater than a thickness of the gate oxide layer 36. The operating voltage applicable to the transistor structure T3 may be higher than the operating voltage applicable to the transistor structure T2 and the operating voltage applicable to the transistor structure T1, and the operating voltage applicable to the transistor structure T2 may be higher than the operating voltage applicable to the transistor structure T1

To summarize the above descriptions, in the manufacturing method of the semiconductor device, by the coordination and the adjustment of the process steps, the pad oxide pattern and a part of the trench isolation structure located within the middle voltage device region and/or the high voltage device region may be removed concurrently by the same etching process for process simplification and/or manufacturing cost reduction.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A manufacturing method of a semiconductor device, comprising:
providing a semiconductor substrate, wherein the semiconductor substrate comprises:
a first portion located within a low voltage device region; and
a second portion located within a middle voltage device region;
forming a first pad oxide pattern and a second pad oxide pattern above the first portion and the second portion, respectively;
forming a first trench isolation structure and a second trench isolation structure, wherein at least a part of the first trench isolation structure is formed in the first portion and located adjacent to the first pad oxide pattern, and at least a part of the second trench isolation structure is formed in the second portion and located adjacent to the second pad oxide pattern; and
performing an etching process, wherein the second pad oxide pattern and a part of the second trench isolation structure are removed concurrently by the etching process.

2. The manufacturing method of the semiconductor device according to claim 1, wherein a top surface of the second trench isolation structure after the etching process is lower than a top surface of the second trench isolation structure before the etching process and a top surface of the first trench isolation structure after the etching process.

3. The manufacturing method of the semiconductor device according to claim 2, wherein a top surface of the first trench isolation structure before the etching process and the top surface of the second trench isolation structure before the etching process are coplanar.

4. The manufacturing method of the semiconductor device according to claim 1, further comprising:
forming a first well region and a second well region in the first portion and the second portion, respectively, after the first trench isolation structure and the second trench isolation structure are formed and before the etching process.

5. The manufacturing method of the semiconductor device according to claim 4, further comprising:
forming a first deep well region and a second deep well region in the first portion and the second portion, respectively, before the first trench isolation structure and the second trench isolation structure are formed, wherein the first well region and the second well region are formed in the first deep well region and the second deep well region, respectively.

6. The manufacturing method of the semiconductor device according to claim 1, further comprising:
forming a first gate oxide layer on the second portion after the etching process, wherein a thickness of the first gate oxide layer is greater than a thickness of the second pad oxide pattern; and
forming an oxide layer on the first portion after the etching process, wherein the first gate oxide layer and the oxide layer are formed concurrently by a formation process, the first pad oxide pattern remains on the first portion after the etching process, and the first pad oxide pattern becomes at least a part of the oxide layer by the formation process.

7. The manufacturing method of the semiconductor device according to claim 6, wherein the formation process comprises an oxidation process.

8. The manufacturing method of the semiconductor device according to claim 6, further comprising:
performing a cleaning process to the semiconductor substrate after the etching process and before the formation process, wherein the first pad oxide pattern remains on the first portion after the cleaning process.

9. The manufacturing method of the semiconductor device according to claim 1, wherein the semiconductor substrate further comprises a third portion located within a high voltage device region, and the manufacturing method of the semiconductor device further comprises:
forming a third pad oxide pattern above the third portion, wherein the first pad oxide pattern, the second pad oxide pattern, and the third pad oxide pattern are formed concurrently by the same process; and
forming a third trench isolation structure, wherein at least a part of the third trench isolation structure is formed in the third portion and located adjacent to the third pad oxide pattern, and the first trench isolation structure, the second trench isolation structure, and the third trench isolation structure are formed concurrently by the same process.

10. The manufacturing method of the semiconductor device according to claim 9, further comprising:
forming a first mask pattern, a second mask pattern, and a third mask pattern above the first portion, the second portion, and the third portion, respectively, before the first trench isolation structure, the second trench isolation structure, and third trench isolation structure are formed, wherein the first pad oxide pattern is sandwiched between the first mask pattern and the first portion in a vertical direction, the second pad oxide pattern is sandwiched between the second mask pattern and the second portion in the vertical direction, and the third pad oxide pattern is sandwiched between the third mask pattern and the third portion in the vertical direction.

11. The manufacturing method of the semiconductor device according to claim 10, further comprising:
forming a first trench, a second trench, and a third trench in the first portion, the second portion, and the third portion, respectively, wherein the first trench isolation structure, the second trench isolation structure, and the third trench isolation structure are formed in the first trench, the second trench, and the third trench, respectively, and the first mask pattern, the second mask pattern, the third mask pattern, the first pad oxide pattern, the second pad oxide pattern, the third pad oxide pattern, the first trench, the second trench, and the third trench are formed by a patterning process performed before the first trench isolation structure, the second trench isolation structure, and the third trench isolation structure are formed.

12. The manufacturing method of the semiconductor device according to claim 9, wherein the third pad oxide pattern and a part of the third trench isolation structure are removed concurrently by the etching process.

13. The manufacturing method of the semiconductor device according to claim 12, wherein a top surface of the third trench isolation structure after the etching process is lower than a top surface of the third trench isolation structure before the etching process and a top surface of the first trench isolation structure after the etching process.

14. The manufacturing method of the semiconductor device according to claim 13, wherein a top surface of the first trench isolation structure before the etching process and the top surface of the third trench isolation structure before the etching process are coplanar.

15. The manufacturing method of the semiconductor device according to claim 9, further comprising:
forming a second gate oxide layer before the etching process, wherein at least a part of the second gate oxide layer is formed in the third portion, and a thickness of the second gate oxide layer is greater than a thickness of the third pad oxide pattern.

16. The manufacturing method of the semiconductor device according to claim 15, further comprising:
forming a fourth pad oxide pattern above the third portion, wherein the first pad oxide pattern, the second pad oxide pattern, the third pad oxide pattern, and the fourth pad oxide pattern are formed concurrently by the same process;
forming a fourth trench isolation structure, wherein at least a part of the fourth trench isolation structure is formed in the third portion and located adjacent to the fourth pad oxide pattern, and the third pad oxide pattern is located between the third trench isolation structure and the fourth trench isolation structure in a horizontal direction; and
forming a recess by removing a part of the semiconductor substrate, a part of the fourth trench isolation structure, and at least a part of the fourth pad oxide pattern, wherein the second gate oxide layer is formed in the recess.

17. The manufacturing method of the semiconductor device according to claim 16, wherein a part of the fourth trench isolation structure is removed by the etching process, and a top surface of the fourth trench isolation structure after the etching process is lower than a top surface of the fourth trench isolation structure before the etching process and a top surface of the first trench isolation structure after the etching process.

18. The manufacturing method of the semiconductor device according to claim 15, further comprising:
forming a patterned mask layer covering the second gate oxide layer, the first pad oxide pattern, and the first trench isolation structure, wherein the second gate oxide layer, the first pad oxide pattern, and the first trench isolation structure are covered by the patterned mask layer during the etching process; and
removing the patterned mask layer after the etching process.

19. The manufacturing method of the semiconductor device according to claim 15, further comprising:
forming a drift region in the third portion after the third trench isolation structure is formed and before the second gate oxide layer is formed.

20. The manufacturing method of the semiconductor device according to claim 19, further comprising:
forming a third deep well region in the third portion before the third trench isolation structure is formed, wherein the drift region is formed in the third deep well region, and a conductivity type of the drift region is complementary to a conductivity type of the third deep well region.
